(19) United States
(12) Patent Application Publication
(10) Pub. No.: US 2025/0343039 A1
(43) Pub. Date: Nov. 6, 2025

(54) SYSTEMS AND METHODS FOR PREVENTING BODY BIASING INJECTION ATTACKS

(71) Applicant: Advanced Micro Devices, Inc., Santa Clara, CA (US)

(72) Inventors: Mohit Arora, Austin, TX (US); Deepak Vasant Kulkarni, Austin, TX (US)

(73) Assignee: Advanced Micro Devices, Inc., Santa Clara, CA (US)

(21) Appl. No.: 18/316,918

(22) Filed: May 12, 2023

(51) Int. Cl. H01L 21/02; H01L 23/00; H01L 23/14; H01L 23/373; H01L 25/065

(52) U.S. Cl. CPC H01L 21/02164; H01L 23/147; H01L 23/3736; H01L 23/576; H01L 24/16; H01L 24/29; H01L 25/0655; H01L 25/0657; H01L 2224/16155; H01L 2224/29099; H01L 2225/1041; H01L 2924/15321

(57) ABSTRACT

A computer-implemented method for preventing body biasing attacks can include providing a stacked silicon die. The method can also include providing an oxide layer on a back side of the stacked silicon die, wherein the oxide layer restricts voltage glitches from reaching a power subsystem of the stacked silicon die. The method can further include permanently attaching a carrier to the oxide layer. Various other methods, systems, and computer-readable media are also disclosed.

### BACKGROUND

Body biasing injection (BBI) attacks use a voltage applied with a physical probe onto the backside of an integrated circuit die. BBI attacks are not as prevalent as other techniques, such as electromagnetic fault injection (EMFI) or Laser Fault Injection (LFI), presumably due to an increased cost of equipment and increased effort required in device preparation. However, BBI attacks are still considered low-cost attacks that involve probing the back side of the die to inject voltage pulses that couple with chip structure.

Wafer-level chip-scale packaging (WLCSP) exposes the back side of the die, making these types of packages particularly vulnerable to BBI attacks. For example, chips of flip chip packages can include all the protection/security on a front side of a die while completely exposing the back side of the die. All that is required is to remove the heat sink, a semi-invasive measure, mounted on the package and, in some cases, thin a silicon carrier. With this meager preparation, a probe can inject a voltage glitch in a power structure of the die by applying bias to the bulk silicon. There exists no current defense against such attacks.

### BRIEF DESCRIPTION OF THE DRAWINGS

The accompanying drawings illustrate a number of example embodiments and are a part of the specification. Together with the following description, these drawings demonstrate and explain various principles of the present disclosure.

FIG. 1 is a flow diagram of an example method for preventing body biasing injection attacks.

FIG. 2 is a block diagram illustrating an example of a body biasing injection attack.

FIG. 3 is a block diagram illustrating example integrated circuits undergoing body biasing injection attacks and demonstrating a countermeasure using a silicon carrier.

FIG. 4 is a block diagram illustrating example integrated circuits undergoing body biasing injection attacks and demonstrating a countermeasure using a glass carrier.

FIG. 5 is a block diagram illustrating an example 3D stacked integrated circuit package.

FIG. 6 is a block diagram illustrating example 2.5D stacked integrated circuit packages.

Throughout the drawings, identical reference characters and descriptions indicate similar, but not necessarily identical, elements. While the example embodiments described herein are susceptible to various modifications and alternative forms, specific embodiments have been shown by way of example in the drawings and will be described in detail herein. However, the example embodiments described herein are not intended to be limited to the particular forms disclosed. Rather, the present disclosure covers all modifications, equivalents, and alternatives falling within the scope of the appended claims.

### DETAILED DESCRIPTION OF EXAMPLE IMPLEMENTATIONS

The present disclosure is generally directed to systems and methods for preventing body biasing injection attacks. For example, by adding an oxide layer (e.g., thickness 1-2 um) on a back side of a stacked silicon die (e.g., between transistors and bulk silicon), voltage glitches can be restricted from reaching a power subsystem of a stacked silicon die package. The oxide layer can function as an electrical insulator that acts as a barrier to injected voltage pulses, thus preventing a low-cost body biasing injection (BBI) attack on the package and one or more security assets (e.g., on a root of trust (ROT) and/or die to die interconnect) of the stacked silicon die. In some implementations, the oxide layer can permanently attach a carrier (e.g., silicon carrier, glass carrier, etc.) on the back side of the package. In some of these implementations, a glass carrier can have thermal vias that are floating (e.g., filled with copper that is not electrically connected). In some of these implementations, the vias do not connect to the base silicon (e.g., are not through holes). These vias can be located in positions to address thermal issues by providing a thermal path while the oxide layer and glass carrier provide electrical insulation. In this way, the oxide layer can provide electrical insulation that protects one or more security assets (e.g., root of trust and/or die to die interconnect) of the stacked silicon die from BBI attacks while also providing sufficient thermal conductivity. In implementations that employ a glass carrier with thermal vias, sufficient thermal conductivity can be provided for applications that do not require a heat sink (e.g., internet of things devices).

In one example, an integrated circuit includes a stacked silicon die an oxide layer provided on a back side of the stacked silicon die, wherein the oxide layer restricts voltage glitches from reaching a power subsystem of the stacked silicon die, and a carrier permanently attached to the oxide layer.

Another example can be the previously described example integrated circuit, wherein the oxide layer has a thickness in a range of one to two micrometers.

Another example can be any of the previously described example integrated circuits, wherein the carrier is a glass carrier having one or more thermal vias formed therein.

Another example can be any of the previously described example integrated circuits, wherein the one or more thermal vias do not connect to the stacked silicon die.

Another example can be any of the previously described example integrated circuits, wherein the carrier is a silicon carrier.

Another example can be any of the previously described example integrated circuits, wherein the oxide layer restricts access to a security asset of the stacked silicon die.

In one example, an integrated circuit package includes an integrated circuit that includes a stacked silicon die and an oxide layer provided on a back side of the stacked silicon die, wherein the oxide layer restricts voltage glitches from reaching a power subsystem of the stacked silicon die, a carrier permanently attached to the oxide layer, and a substrate attached to a front side of the stacked silicon die.

Another example can be the previously described integrated circuit package, wherein the oxide layer has a thickness in a range of one to two micrometers.

Another example can be any of the previously described integrated circuit packages, wherein the carrier is a glass carrier having one or more thermal vias formed therein, the integrated circuit further including a thermally conductive material filling at least part of the one or more thermal vias.

Another example can be any of the previously described integrated circuit packages, wherein the one or more thermal vias do not connect to the stacked silicon die.

Another example can be any of the previously described integrated circuit packages, wherein the carrier is a silicon carrier.

Another example can be any of the previously described integrated circuit packages, wherein the oxide layer restricts access to a security asset of the stacked silicon die.

Another example can be any of the previously described integrated circuit packages, wherein the security asset corresponds to at least one of a root of trust of the stacked silicon die or a die to die interconnect of the stacked silicon die.

Another example can be any of the previously described integrated circuit packages, wherein the stacked silicon die includes two or more 3D stacked silicon dies.

Another example can be any of the previously described integrated circuit packages, wherein the stacked silicon die includes multiple silicon dies stacked on an interposer.

In one example, a method includes providing a stacked silicon die, providing an oxide layer on a back side of the stacked silicon die, wherein the oxide layer restricts voltage glitches from reaching a power subsystem of the stacked silicon die, and permanently attaching a carrier to the oxide layer.

Another example can be the previously described method, wherein the oxide layer has a thickness in a range of one to two micrometers.

Another example can be any of the previously described methods, wherein the carrier is a glass carrier having one or more thermal vias formed therein.

Another example can be any of the previously described methods, wherein the one or more thermal vias do not connect to the stacked silicon die.

Another example can be any of the previously described methods, wherein the carrier is a silicon carrier.

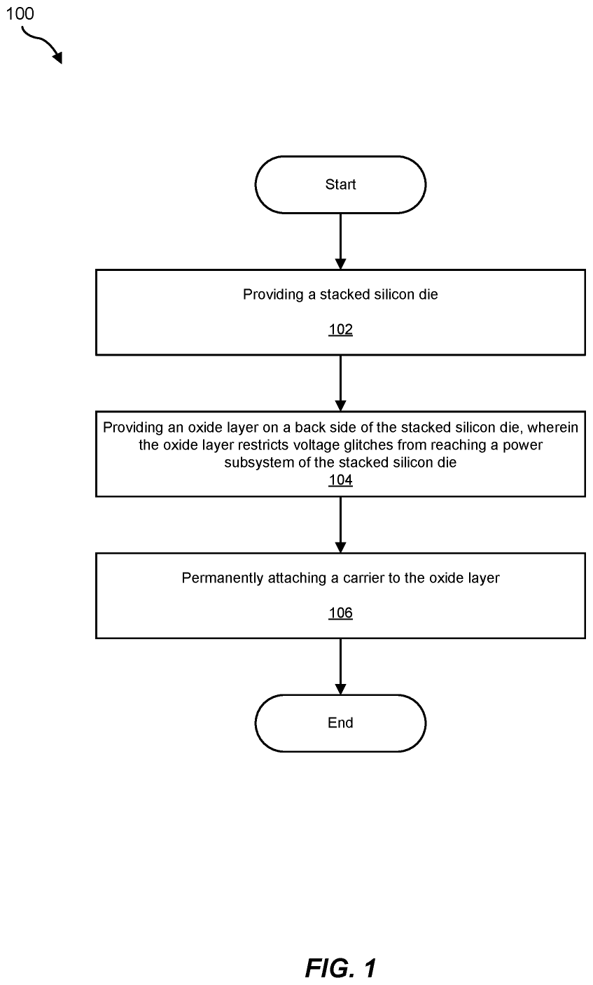

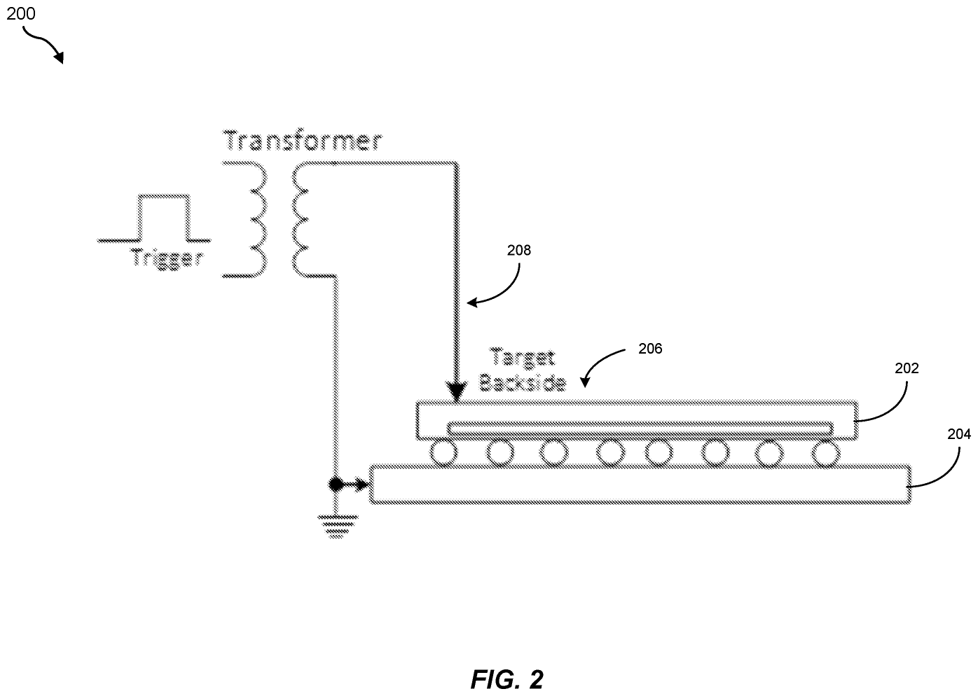

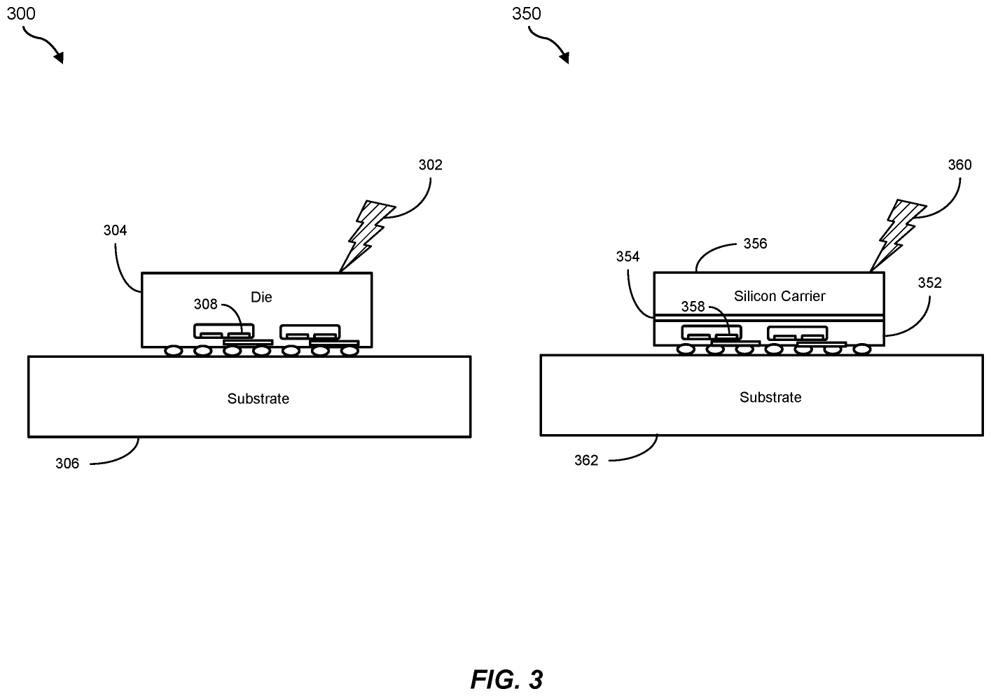

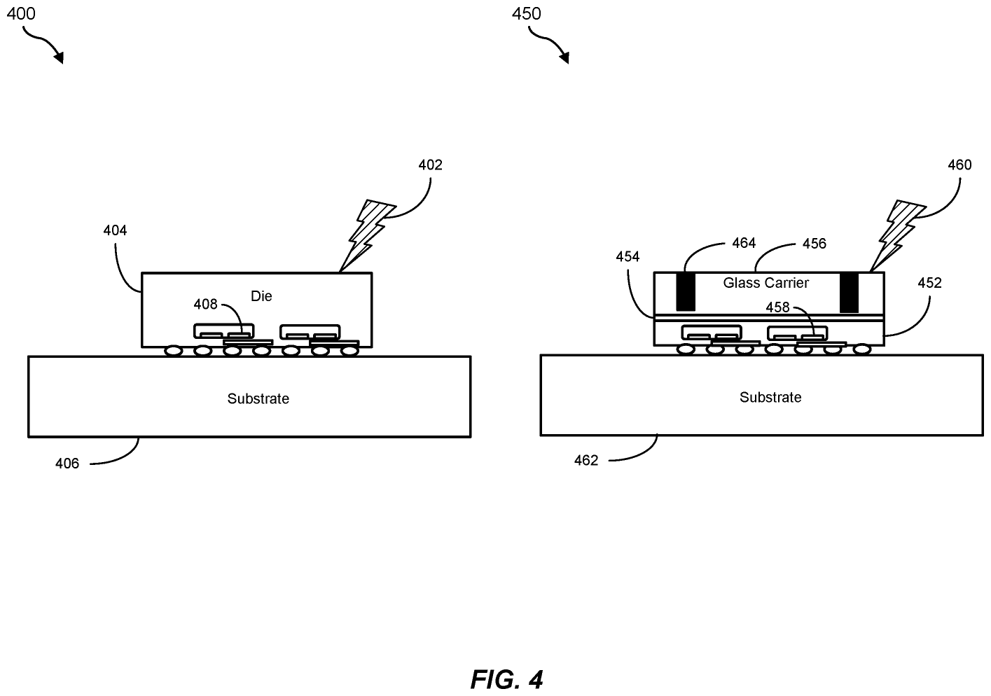

The following will provide, with reference to FIG. 1, detailed descriptions of an example method for preventing body biasing injection attacks. In addition, detailed descriptions of an example body biasing injection attack will be provided in connection with FIG. 2. Also, detailed descriptions of example integrated circuits undergoing body biasing injection attacks will be provided in connection with FIGS. 3 and 4.

FIG. 1 illustrates an example method 100 for preventing body biasing injection attacks. The steps shown in FIG. 1 can be performed by any suitable computer-executable code and/or computing system. In one example, each of the steps shown in FIG. 1 can represent an algorithm whose structure includes and/or is represented by multiple sub-steps, examples of which will be provided in greater detail below.

As illustrated in FIG. 1, step 102 can include providing a die. For example, step 102 can include providing a stacked silicon die.

The term “stacked silicon die,” as used herein, can generally refer to a process of mounting multiple chips on top of each other within a single semiconductor package. Die stacking, which is also known as “chip stacking,” significantly increases the amount of silicon chip area that can be housed within a single package of a given footprint, conserving precious real estate on the printed circuit board and simplifying the board assembly process. Aside from space savings, die stacking also results in better electrical performance of the device, since the shorter routing of interconnections between circuits results in faster signal propagation and reduction in noise and cross-talk. A stacked silicon die can be formed using a wafer on wafer or chip on wafer process.

The term “wafer on wafer,” as used herein, can generally refer to a wafer fabrication process. For example, and without limitation, wafer on wafer can refer to a procedure composed of two or more repeated sequential processes to produce complete electrical or photonic circuits on semiconductor wafers in a semiconductor device fabrication process. Examples include production of radio frequency (RF) amplifiers, LEDs, optical computer components, and microprocessors for computers. Wafer fabrication can be used to build components with the necessary electrical structures. In this context, “wafer on wafer stacked silicon die” can generally refer to silicon die stacking by a wafer on wafer process as opposed to chip on wafer process, in which a wafer is diced into chips before placement thereof onto a wafer. A wafer on wafer process can yield reduced costs compared to a chip on wafer process.

The systems described herein can perform step 102 in a variety of ways. In one example, step 102 can include receiving a prefabricated stacked silicon die and placing it on a workstation (e.g., in an ultra-clean environment). Alternatively, step 102 can include manufacturing the stacked silicon die. In some of these implementations, manufacturing the stacked silicon die can include placing a substrate and/or carrier on a workstation (e.g., in an ultra-clean environment) and forming a silicon wafer on the carrier and/or substrate. In some of these implementations, multiple wafers can be formed one atop another. In some implementations, one or more of the wafers can be thinned to reveal vias and/or hybrid bonds prior to formation of a next wafer. In some of these implementations, one or more of the wafers can include transistors configured as one or more microprocessors that constitute one or more security assets (e.g., a root of trust of the stacked silicon die and/or a die to die interconnect of the stacked silicon die). In some implementations, a substrate (e.g., bulk silicon), can be formed atop a carrier and/or oxide layer. In some implementations, a carrier and/or substrate can be removed following formation of the wafers. In other implementations, a substrate and/or carrier can be permanently attached. Alternatively or additionally, a substrate (e.g., bulk silicon) including all or part of a power subsystem can form part of the stacked silicon die.

The term “root of trust,” as used herein, can generally refer to a logic block that resides in a silicon die that maintains the trust. For example, and without limitation, a root of trust can maintain a trust using one or more encryption schemes, digital signatures, and/or secret keys. In use, a root of trust (ROT) can be implemented as a source that can always be trusted within a cryptographic system. Because cryptographic security is dependent on keys to encrypt and decrypt data and perform functions such as generating digital signatures and verifying signatures, ROT schemes generally include a hardened hardware module. In this context, a hardware root of trust can be the foundation on which all secure operations of a computing system depend. It can contain the keys used for cryptographic functions and enable a secure boot process. It is inherently trusted, and therefore must be secure by design. The most secure implementation of a root of trust is in hardware making it immune from malware attacks. As such, it can be a stand-alone security module or implemented as a security module within a processor or system on chip (SoC).

The term “die to die interconnect,” as used herein, can generally refer to one or more communication media (e.g., metal layers, vias, hybrid bonds, direct bonds, bumps, etc.) that provide communication capabilities (e.g., power and/or signal (e.g., data)) between two dies. For example, and without limitation, two or more chips located in a same layer of a stacked silicon die can be connected by vias to one or more metal layers in a lower level of the stacked silicon die. Alternatively or additionally, two or more silicon dies can be mounted on an interposer or substrate (e.g., by bumps, vias, hybrid bonds, direct bonding, etc.) having metal layers therein that provide communication between the dies. Die to die interconnects can sometimes be fully exposed upon decapsulation of an integrated circuit package. This die to die interconnect is a security asset that can benefit from protection.

Step 104 can include providing an oxide layer. For example, step 104 can include providing an oxide layer on a back side of the stacked silicon die, wherein the oxide layer restricts voltage glitches from reaching a power subsystem of the stacked silicon die.

The term “oxide layer,” as used herein, can generally refer to a thin layer or coating of an oxide that provides electrical insulation, such as silicon dioxide. For example, oxide layer can generally refer to magnesium oxide (MgO), aluminum oxide (Al2O3), silicon dioxide (SiO2), a transition metal oxide (e.g., titanium dioxide (TiO2), strontium titanate (SrTiO3)), any other oxide that is an electrical insulator, and combinations thereof.

The term “voltage glitch,” as used herein, can generally refer to violent modification of a supply voltage of a circuit for a very short time, so that it ends up in an inappropriate state. For example, and without limitation, voltage glitch can refer to active side channel attacks that modify the execution-flow of a device by creating disturbances on the power supply line, thus skipping security checks or generating side-channels that gradually leak sensitive data, including the firmware code. Alternatively or additionally, voltage glitch can refer, without limitation, to attacks that involve causing a hardware fault through manipulating the environmental variables in a system. Such a hardware fault can be temporary or persistent across power cycles (e.g., permanent).

The term “power subsystem,” as used herein, can generally refer to components that deliver power to attached instruments and sensors. For example, and without limitation, a power subsystem can begin with power feed equipment and end with final output voltage converter and filters. Depending on implementation, either constant current or constant voltage power feeding may be used.

The systems described herein can perform step 104 in a variety of ways. In one example, the oxide layer can be deposited on the back side of the stacked silicon die by thermal oxidation, wet anodization, chemical vapor deposition, and/or plasma anodization or oxidation. In some examples, the oxide layer can include silicon dioxide (SiO₂). In other examples, the oxide layer can include magnesium oxide (MgO), aluminum oxide (Al2O3), silicon dioxide (SiO₂), a transition metal oxide (e.g., titanium dioxide (TiO2), strontium titanate (SrTiO3)), any other oxide that is an electrical insulator, and combinations thereof. In some examples, the oxide layer can have a thickness in a range of one to two micrometers. This thickness can be tuned during deposition and/or by thinning thereof to modify the breakdown voltage of the oxide layer.

Step 106 can include attaching a carrier. For example, step 106 can include permanently attaching a carrier to the oxide layer.

The term “carrier,” as used herein, can generally refer to a surface-mount technology package for integrated circuits. For example, and without limitation, carriers can be glass carriers, quartz carriers, or silicon carriers. Bottom carriers can be employed as a base platform in a stacking process (e.g., wafer on wafer or chip on wafer) to provide structural support during wafer chip manufacture. Such carriers can often be removed before, during, or after packaging the integrated circuit. Top carriers can be added on top of an integrated circuit for protection and structural support. Top carriers can also be removed before, during, or after packaging of the integrated circuit.

The term “glass carrier,” as used herein, can generally refer to precision planes (e.g., disks) of thin glass, such as borosilicate glass. For example, and without limitation, glass carriers can be created by selecting an appropriate high-quality glass material and then carefully cutting and shaping it. Numerous finishing processes can be performed to perfect the carrier wafer's flatness before it undergoes rigorous quality inspection processes using precision laser measuring equipment. Although glass carriers are typically removed from semiconductor devices, cleaned, and reused, the systems and methods of the present disclosure can permanently attach a glass carrier to a backside of an integrated circuit as part of a packaging process. According to the disclosed systems and methods, any glass carrier capable of functioning as an electrical insulator can be used. A glass carrier can, thus, be distinguished from a silicon carrier because a silicon carrier is typically composed of silicon dioxide, which is not functionally effective as an electrical insulator but provides significantly greater thermal conductivity compared to a glass carrier.

The systems described herein can perform step 106 in a variety of ways. In one example, the oxide layer can be used to bond a glass carrier to the back side of the stacked silicon die. In some examples, the glass carrier can have one or more thermal vias formed therein. In some implementations, the one or more thermal vias do not connect to the stacked silicon die (e.g., are not through holes). In some examples, step 106 can include filling at least part of the one or more thermal vias with a thermally conductive material, such as a metal (e.g., copper) as described later and in greater detail with reference to FIG. 4. Characteristics of the glass carrier (e.g., carrier thickness, number, size, and/or position of thermal vias, type and/or amount of thermally conductive material) can be tuned for different integrated circuits to provide suitable electrical insulation and thermal conductivity. In this way, the oxide layer can provide electrical insulation that protects one or more security assets (e.g., root of trust or die to die interconnect) of the stacked silicon die from BBI attacks while also providing sufficient thermal conductivity for applications that do not require a heat sink (e.g., internet of things devices). Alternatively, step 106 can include using the oxide layer to bond a silicon carrier to the back side of the stacked silicon die. In this way, the oxide layer can provide electrical insulation that protects one or more security assets (e.g., root of trust or die to die interconnect) of the stacked silicon die from BBI attacks while the oxide layer and silicon carrier also provide sufficient thermal conductivity.

An order and/or manner in which steps 102, 104, and 106 are carried out can vary in numerous ways. For example, a carrier can be placed on a workstation in step 106, followed by formation of an oxide layer on the carrier in step 104. Then, the die can be placed or formed on the oxide layer in step 102 with the backside of the die in contact with the oxide layer. In some implementations in which the carrier is a glass carrier, the glass carrier can already have one or more thermal vias formed therein when it is placed on the workstation in step 106. Alternatively or additionally, one or more thermal vias may be formed in the glass carrier during or after step 104 and/or step 102. Further alternatives include placing a prefabricated die on the oxide layer in step 102 or manufacturing the die on the oxide layer. The carrier can remain permanently bonded to the backside of the die by the oxide layer. Alternatively, the oxide layer can be formed on the backside of the die at step 104 and the carrier can be placed atop the oxide layer in step 106. Stated differently, there are at least two options for attaching the carrier. In a first option, the carrier can be used as a bottom carrier having the oxide layer formed thereon and the stacked silicon die placed or formed on the oxide layer. The resulting integrated circuit can be flipped and packaged without removing the bottom carrier, which can function as a top carrier as a result of the flip. In a second option, the stacked silicon die can be flipped and the oxide layer can be provided thereafter and used to bond the carrier as a top carrier.

FIG. 2 illustrates an example 200 of a body biasing injection attack. For example, a flip chip package can have a stacked silicon die 202 and a substrate 204. The die 202 can include a power subsystem. A back side 206 of the die 202 can be exposed to a probe 208 during a BBI attack in which a resistance of the bulk silicon of the die 202 forms an RC circuit with elements of the power subsystem when the probe 208 injects one or more voltage pulses. Formation of this RC circuit can cause abnormal behavior of the power subsystem and potentially cause abnormal behavior of a security asset of the die 202, such as a root of trust and/or die to die interconnect.

FIG. 3 illustrates example integrated circuits 300 and 350 undergoing body biasing injection attacks. For example, integrated circuit 300 is vulnerable to injection of voltage pulses 302 because a backside of the die 304 is exposed. These voltage pulses 302 can travel through the die 304 and substrate 306. Thus, a security asset 308, such as a root of trust and/or die to die interconnect of the die 304, can be caused to exhibit abnormal behavior by injection of voltage pulses 302.

In contrast to integrated circuit 300, integrated circuit 350 can implement one or more features previously described with reference to FIG. 1. For example, a backside of stacked silicon die 352 can have an oxide layer 354 formed thereon. Oxide layer 354 can be deposited on the back side of the stacked silicon die 352 by thermal oxidation, wet anodization, chemical vapor deposition, and/or plasma anodization or oxidation. In some examples, the oxide layer 354 can include silicon dioxide (SiO₂). In other examples, the oxide layer can include magnesium oxide (MgO), aluminum oxide (Al2O3), silicon dioxide (SiO₂), a transition metal oxide (e.g., titanium dioxide (TiO2), strontium titanate (SrTiO3)), any other oxide that is an electrical insulator, and combinations thereof. In some examples, the oxide layer 354 can have a thickness in a range of one to two micrometers. This thickness can be tuned during deposition and/or by thinning thereof to modify the breakdown voltage of the oxide layer 354. Oxide layer 354 can provide electrical insulation that protects one or more security assets 358 (e.g., root of trust and/or die to die interconnect) of the stacked silicon die 352 from voltage pulses 360 injected by BBI attacks while also providing sufficient thermal conductivity for some applications that do not require a heat sink (e.g., internet of things devices). In this way, voltage pulses 360 can be prevented from travelling through the die 352 and substrate 362.

In some implementations, the backside of stacked silicon die 352 also can have a silicon carrier 356 bonded thereto by oxide layer 354. Characteristics of the glass carrier (e.g., carrier thickness) can be tuned for different integrated circuits to provide suitable thermal conductivity. In some implementations, a heat sink can be provided atop the silicon carrier. Together, oxide layer 354 can provide electrical insulation that protects one or more security assets 358 (e.g., root of trust and/or die to die interconnect) of the stacked silicon die 352 from voltage pulses 360 injected by BBI attacks while the oxide layer 354 and silicon carrier 356 also provide sufficient thermal conductivity for various types of applications, including applications that require a heat sink. In this way, voltage pulses 360 can be prevented from travelling through the die 352 and substrate 362.

FIG. 4 illustrates example integrated circuits 400 and 450 undergoing body biasing injection attacks. For example, integrated circuit 400 is vulnerable to injection of voltage pulses 402 because a backside of the die 404 is exposed. These voltage pulses 402 can travel through the die 404 and substrate 406. Thus, a security asset 408, such as a root of trust and/or die to die interconnect of the die 404, can be caused to exhibit abnormal behavior by injection of voltage pulses 402.

In contrast to integrated circuit 400, integrated circuit 450 can implement one or more features previously described with reference to FIGS. 1 and 3. For example, a backside of stacked silicon die 452 can have an oxide layer 454 formed thereon. Oxide layer 454 can be deposited on the back side of the stacked silicon die 452 by thermal oxidation, wet anodization, chemical vapor deposition, and/or plasma anodization or oxidation. In some examples, the oxide layer 454 can include silicon dioxide (SiO₂). In other examples, the oxide layer 454 can include magnesium oxide (MgO), aluminum oxide (Al2O3), silicon dioxide (SiO₂), a transition metal oxide (e.g., titanium dioxide (TiO2), strontium titanate (SrTiO3)), any other oxide that is an electrical insulator, and combinations thereof. In some examples, the oxide layer 454 can have a thickness in a range of one to two micrometers. This thickness can be tuned during deposition and/or by thinning thereof to modify the breakdown voltage of the oxide layer 454. Oxide layer 454 can provide electrical insulation that protects one or more security assets 458 (e.g., root of trust and/or die to die interconnect) of the stacked silicon die 452 from voltage pulses 460 injected by BBI attacks while also providing sufficient thermal conductivity for some applications that do not require a heat sink (e.g., internet of things devices). In this way, voltage pulses 460 can be prevented from travelling through the die 452 and substrate 462.

In some implementations, the backside of stacked silicon die 452 also can have a glass carrier 456 bonded thereto by oxide layer 454. Characteristics of the glass carrier (e.g., carrier thickness) can be tuned for different integrated circuits to provide suitable electrical insulation and thermal conductivity. Together, glass carrier 456 and oxide layer 454 can provide electrical insulation that protects one or more security assets 458 (e.g., root of trust and/or die to die interconnect) of the stacked silicon die 452 from voltage pulses 460 injected by BBI attacks while also providing sufficient thermal conductivity for some applications that do not require a heat sink (e.g., internet of things devices). In this way, voltage pulses 460 can be prevented from travelling through the die 452 and substrate 462.

In some implementations, the glass carrier 456 can have one or more thermal vias 464 formed therein. In some implementations, the one or more thermal vias 464 do not connect to the stacked silicon die 452 (e.g., are not through holes). In some examples, the one or more thermal vias 464 can be filled entirely or in part with a thermally conductive material, such as a metal (e.g., copper). Characteristics of the one or more thermal vias 464 (e.g., number, size, and/or position, type and/or amount of thermally conductive material) can be tuned for different integrated circuits to provide suitable electrical insulation and thermal conductivity. In this way, the glass carrier 456 and oxide layer 454 can provide electrical insulation that protects one or more security assets 458 (e.g., root of trust and/or die to die interconnect) of the stacked silicon die 452 from BBI attacks while also providing sufficient thermal conductivity for applications that do not require a heat sink (e.g., internet of things devices).

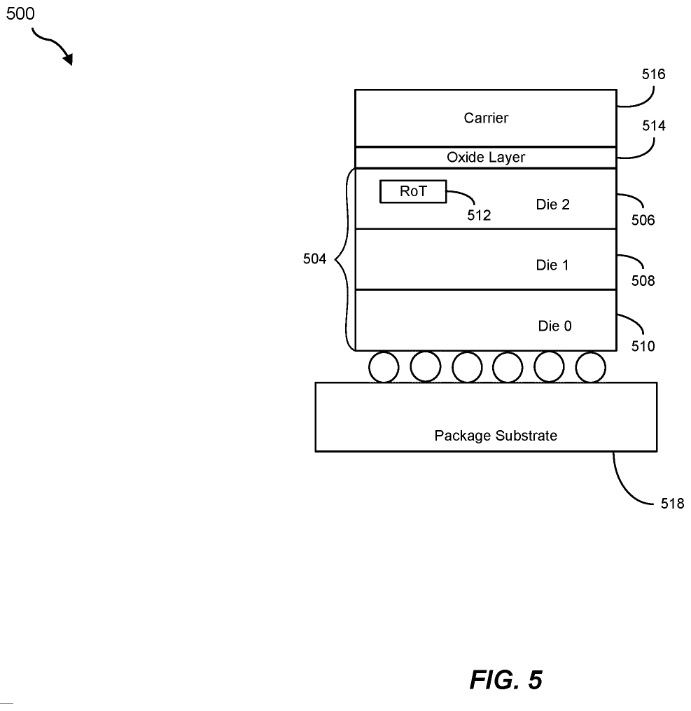

FIG. 5 illustrates an example 3D stacked integrated circuit package 500. For example, a stacked silicon die 504 can include of multiple stacked silicon dies stacked atop one another, such as top silicon die 506, middle silicon die 508, and bottom silicon die 510. A security asset 512, such as a root of trust, can be located in any or all of the silicon dies 506-510. Oxide layer 514 can be provided atop a back side of the stacked silicon die 504, such as atop a back side of top silicon die 506. A carrier 516 can be permanently attached to the back side of stacked silicon die 504 by oxide layer 514. Carrier 516 can correspond to a silicon carrier or a glass carrier as previously described with reference to FIGS. 3 and 4. In implementations in which carrier 516 corresponds to a glass carrier, the glass carrier can have one or more thermal vias as described with reference to FIG. 4. Front side of stacked silicon die 504 can be attached to a package substrate 518 using, for example, bumps and/or microbumps. In this way, oxide layer 514 can provide electrical insulation that prevents back side fault injection attacks on security asset 512.

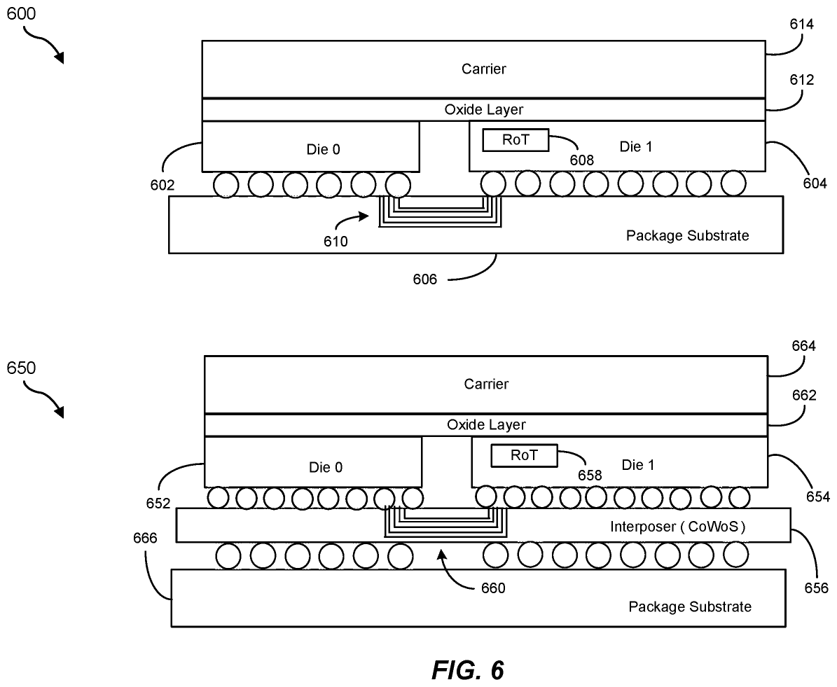

FIG. 6 is a block diagram illustrating example 2.5D stacked integrated circuit packages 600 and 650. For example, a stacked silicon die can correspond to two or more silicon dies 602 and 604 stacked in a 2.5D configuration on a package substrate 606. Any or all of stacked silicon dies 602 and 604 can correspond to single dies, multiple dies stacked in a 3D manner, and/or combination thereof. A security asset 608, such as a root of trust, can be located in any or all of the silicon dies 602 and 604. Alternatively or additionally, a security asset 610, such as a die to die interconnect, can be located in the package substrate 606. Oxide layer 612 can be provided atop a back side of the stacked silicon die, such as atop back sides of silicon dies 602 and 604. A carrier 614 can be permanently attached to the back side of the stacked silicon die by oxide layer 612. Carrier 614 can correspond to a silicon carrier or a glass carrier as previously described with reference to FIGS. 3 and 4. In implementations in which carrier 614 corresponds to a glass carrier, the glass carrier can have one or more thermal vias as described with reference to FIG. 4. A front side of the stacked silicon die can be attached to the package substrate 606 using, for example, bumps and/or microbumps. In this way, oxide layer 612 can provide electrical insulation that prevents back side fault injection attacks on security assets 608 and/or 610.

Example 2.5D stacked integrated circuit package 650 demonstrates a stacked silicon die that can correspond to two or more silicon dies 652 and 654 stacked in a 2.5D configuration on an interposer 656. Any or all of stacked silicon dies 652 and 654 can correspond to single dies, multiple dies stacked in a 3D manner, and/or combination thereof. A security asset 658, such as a root of trust, can be located in any or all of the silicon dies 652 and 654. Alternatively or additionally, a security asset 660, such as a die to die interconnect, can be located in the interposer 656. Oxide layer 662 can be provided atop a back side of the stacked silicon die, such as atop back sides of silicon dies 652 and 654. A carrier 664 can be permanently attached to the back side of the stacked silicon die by oxide layer 662. Carrier 664 can correspond to a silicon carrier or a glass carrier as previously described with reference to FIGS. 3 and 4. In implementations in which carrier 664 corresponds to a glass carrier, the glass carrier can have one or more thermal vias as described with reference to FIG. 4. A front side of the stacked silicon die can be attached to a side of the interposer 656 using, for example, bumps and/or microbumps. An opposite side of the interposer 656 can be attached to a package substrate 666 using, for example, bumps and/or microbumps. In this way, oxide layer 662 can provide electrical insulation that prevents back side fault injection attacks on security assets 658 and/or 660.

As set forth above, the systems and methods disclosed herein can prevent body biasing injection attacks. For example, by adding an oxide layer (e.g., thickness 1-2 um) on a back side of a stacked silicon die (e.g., between transistors and bulk silicon), voltage glitches can be restricted from reaching a power subsystem of a stacked silicon die package. The oxide layer can function as an electrical insulator that acts as a barrier to injected voltage pulses, thus preventing a low-cost body biasing injection (BBI) attack on the package and one or more security assets (e.g., on a root of trust (ROT) and/or die to die interconnect) of the stacked silicon die. In some implementations, the oxide layer can permanently attach a carrier (e.g., silicon carrier, glass carrier, etc.) on the back side of the package. A glass carrier can also function as an electrical insulator that acts as a barrier to injected voltage pulses, thus further preventing the low-cost body BBI attack on the package. In some of these implementations, the glass carrier can have thermal vias that are floating (e.g., filled with copper that is not electrically connected). In some of these implementations, the vias do not connect to the base silicon (e.g., are not through holes). These vias can be located in positions to address thermal issues by providing a thermal path while the oxide layer and glass carrier provide electrical insulation. In this way, the oxide layer and, optionally, a glass carrier can provide electrical insulation that protects one or more security assets (e.g., root of trust and/or die to die interconnect) of the stacked silicon die from BBI attacks while also providing sufficient thermal conductivity for applications that do not require a heat sink (e.g., internet of things devices).

While the foregoing disclosure sets forth various implementations using specific block diagrams, flowcharts, and examples, each block diagram component, flowchart step, operation, and/or component described and/or illustrated herein can be implemented, individually and/or collectively, using a wide range of hardware, software, or firmware (or any combination thereof) configurations. In addition, any disclosure of components contained within other components should be considered example in nature since many other architectures can be implemented to achieve the same functionality.

The process parameters and sequence of steps described and/or illustrated herein are given by way of example only and can be varied as desired. For example, while the steps illustrated and/or described herein can be shown or discussed in a particular order, these steps do not necessarily need to be performed in the order illustrated or discussed. The various example methods described and/or illustrated herein can also omit one or more of the steps described or illustrated herein or include additional steps in addition to those disclosed.

While various implementations have been described and/or illustrated herein in the context of fully functional computing systems, one or more of these example implementations can be distributed as a program product in a variety of forms, regardless of the particular type of computer-readable media used to actually carry out the distribution. The implementations disclosed herein can also be implemented using modules that perform certain tasks. These modules can include script, batch, or other executable files that can be stored on a computer-readable storage medium or in a computing system. In some implementations, these modules can configure a computing system to perform one or more of the example implementations disclosed herein.

The preceding description has been provided to enable others skilled in the art to best utilize various aspects of the example implementations disclosed herein. This example description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. An integrated circuit, comprising:
a stacked silicon die;
an oxide layer provided on a back side of the stacked silicon die, wherein the oxide layer restricts voltage glitches from reaching a power subsystem of the stacked silicon die; and
a carrier permanently attached to the oxide layer.

2. The integrated circuit of claim 1, wherein the oxide layer has a thickness in a range of one to two micrometers.

3. The integrated circuit of claim 1, wherein the carrier is a glass carrier having one or more thermal vias formed therein.

4. The integrated circuit of claim 3, wherein the one or more thermal vias do not connect to the stacked silicon die.

5. The integrated circuit of claim 1, wherein the carrier is a silicon carrier.

6. The integrated circuit of claim 1, wherein the oxide layer restricts access to a security asset of the stacked silicon die.

7. An integrated circuit package, comprising:
an integrated circuit that includes:
a stacked silicon die; and
an oxide layer provided on a back side of the stacked silicon die, wherein the oxide layer restricts voltage glitches from reaching a power subsystem of the stacked silicon die;
a carrier permanently attached to the oxide layer; and
a substrate attached to a front side of the stacked silicon die.

8. The integrated circuit package of claim 7, wherein the oxide layer has a thickness in a range of one to two micrometers.

9. The integrated circuit package of claim 7, wherein the carrier is a glass carrier having one or more thermal vias formed therein, the integrated circuit further comprising:
a thermally conductive material filling at least part of the one or more thermal vias.

10. The integrated circuit package of claim 9, wherein the one or more thermal vias do not connect to the stacked silicon die.

11. The integrated circuit package of claim 7, wherein the carrier is a silicon carrier.

12. The integrated circuit package of claim 7, wherein the oxide layer restricts access to a security asset of the stacked silicon die.

13. The integrated circuit package of claim 12, wherein the security asset corresponds to at least one of a root of trust of the stacked silicon die or a die to die interconnect of the stacked silicon die.

14. The integrated circuit package of claim 7, wherein the stacked silicon die includes two or more 3D stacked silicon dies.

15. The integrated circuit package of claim 7, wherein the stacked silicon die includes multiple silicon dies stacked on an interposer.

16. A method comprising:
providing a stacked silicon die;
providing an oxide layer on a back side of the stacked silicon die, wherein the oxide layer restricts voltage glitches from reaching a power subsystem of the stacked silicon die; and
permanently attaching a carrier to the oxide layer.

17. The method of claim 16, wherein the oxide layer has a thickness in a range of one to two micrometers.

18. The method of claim 16, wherein the carrier is a glass carrier having one or more thermal vias formed therein.

19. The method of claim 18, wherein the one or more thermal vias do not connect to the stacked silicon die.

20. The method of claim 16, wherein the carrier is a silicon carrier.
